(19) United States
(12) Patent Application Publication
(10) Pub. No.: US 2023/0314701 A1
(43) Pub. Date: Oct. 5, 2023

(54) ELECTRICAL-OPTICAL BRIDGE CHIP AND INTEGRATED CIRCUIT PACKAGING STRUCTURE

(71) Applicant: International Business Machines Corporation, Armonk, NY (US)

(72) Inventors: Frank Robert Libsch, White Plains, NY (US); Kamal K. Sikka, Poughkeepsie, NY (US); Arvind Kumar, Chappaqua, NY (US)

(21) Appl. No.: 17/712,332

(22) Filed: Apr. 4, 2022

(51) Int. Cl. G02B 6/12; G02B 6/43; H01L 23/498; H01L 23/48

(52) U.S. Cl. CPC G02B 6/12004; G02B 6/43; H01L 23/49816; H01L 23/481

(57) ABSTRACT

A bridge chip of an IC packaging structure includes E/O and O/E converters and a first wiring pattern interconnecting the converters to host chips and a second wiring pattern electrically connected to the host chips. An optical interface outputs the optical signals from a backside surface of the bridge chip. The optical interface receives optical signals through the backside surface. Electrical through links connected to the second wiring pattern output electrical signals generated by the host chips through the backside surface of the bridge chip. The packaging structure includes substrate with a trench provided in the top surface of the substrate and the bridge chip disposed in the trench. The host chips are directly connected to the top surface of the bridge chip and the top surface of the substrate. Optical signals are output from the packaging structure through an opening in the bottom surface of the substrate.

### BACKGROUND

The present invention relates generally to integrated circuits, and more particularly, to electrical-optical bridge chip structures to interconnect integrated circuit chips in integrated circuit packaging structures.

A continuing focus of the microelectronics industry is the enablement of integrated circuit structures with electro-optical modules having greater density, higher performance, and lower cost. In a typical 100 Gb/s system, a medium reach interface is required between the host chip and the optical module. The host chip and optical module both need an interface layer that needs to be able to drive a channel with up to 15 dB of loss at the fundamental frequency. The optical module requires a driver, a trans-impedance amplifier, an electro-optical converter and an optical-electro converter. For 100 m links, a retiming function is also needed on the optical module in order to close the electrical-optical-electrical link budget.

In one known system, two all-electrical integrated circuit chips are adhered to a bridge chip made of silicon on insulator (SOI) in which a thin layer of silicon sits over an electrically-insulating oxide of silicon. This SOI is necessary in photonics because the insulating oxide traps the light so that it may be steered along the wafer surface using waveguides. The prior art system uses data links that are no more than about 10 cm. Fundamentally, this technology would be limited by the size of the SOI wafers, typically 30 cm. The bridge chip electrically bonds to host chips and provides a lateral optical interconnect between chips. However, the bridge provides optical interconnects that do not leave the silicon bridge which significantly complicates and/or limits the ability to interconnect with multiple package levels. In addition, there are no electrical links parallel to the optical links to interconnect the host chips to multiple host chips. The lack of these features limits the performance, resulting in increased cost to meet the demands for greater density and higher performance.

### SUMMARY

In some embodiments, a bridge chip having electrical through links and an optical interface is disclosed. The electrical through links provide a short reach to multiple host chips mounted on the bridge chip for data coordination, communication, etc., between the host chips. The optical interface provides a long reach with higher bandwidth density to communicate optically with multiple integrated circuit (IC) packaging structures.

In one embodiment, a bridge chip includes first and second opposing surfaces, the first opposing surface having a plurality of first electrical connections and a plurality of second electrical connections. The bridge chip includes at least one converter, the at least one converter being at least one of an electro-optical converter and an optical-electro converter. The electro-optical converter is configured to convert an electrical signal to an optical signal and the optical-electro converter is configured to convert an optical signal to an electrical signal. The bridge chip includes a first wiring pattern interconnecting the least one converter to a corresponding at least one host chip using the plurality of first electrical connections and a second wiring pattern electrically connected to the at least one host chip using the plurality of second electrical connections. In some embodiments, the bridge chip includes an optical interface configured to output the optical signals generated by the at least one electro-optical converter from the second opposing surface and configured to receive optical signals through the second opposing surface and to transmit the received optical signals to the at least one optical-electro converter. In some embodiments, the bridge chip includes at least one electrical through link connected to the second wiring pattern, the at least one electrical through link extending from the first opposing surface to the second opposing surface, the at least one electrical through link being configured to output electrical signals from the at least one host chip.

In one embodiment, an integrated circuit packaging structure includes a packaging substrate having first and second opposing surfaces, a trench provided in the first opposing surface of the packaging substrate and a bridge chip disposed in the trench. In one embodiment, a bridge chip includes first and second opposing surfaces, the first opposing surface having a plurality of first electrical connections and a plurality of second electrical connections. The bridge chip includes at least one converter, the at least one converter being at least one of an electro-optical converter and an optical-electro converter. The electro-optical converter is configured to convert an electrical signal to an optical signal and the optical-electro converter is configured to convert an optical signal to an electrical signal. The bridge chip includes a first wiring pattern interconnecting the least one converter to a corresponding at least one host chip using the plurality of first electrical connections and a second wiring pattern electrically connected to the at least one host chip using the plurality of second electrical connections. The packaging structure includes an opening provided in the second opposing surface of the packaging substrate, the opening extending to the second opposing surface of the bridge chip. At least one host chip is overlying the first opposing surface of the bridge chip and the first opposing surface of the packaging substrate, the at least one host chip is directly connected to the first opposing surface of the bridge chip and the first opposing surface of the packaging substrate by a plurality of electrical connections. The optical signals are output from the integrated circuit packaging structure through the opening in the second opposing surface of the packaging substrate.

In one embodiment of a method for forming an integrated circuit packaging structure includes providing a packaging substrate having first and second opposing surfaces, forming a trench in the first opposing surface of the packaging substrate, forming an opening in the packaging substrate extending from the trench to the second opposing surface and placing a bridge chip in the trench. In some embodiments, the bridge chip includes first and second opposing surfaces, the first opposing surface having a plurality of first electrical connections and a plurality of second electrical connections, at least one converter that includes at least one of an electro-optical converter and an optical-electro converter, a first wiring pattern interconnecting the least one converter to a corresponding at least one host chip using the plurality of first electrical connections; and a second wiring pattern electrically connected to the at least one host chip using the plurality of second electrical connections. The method further includes connecting the at least one host chip to the first opposing surface of the bridge chip and the first opposing surface of the packaging substrate, the at least one host chip being directly connected to the first opposing surface of the bridge chip and the first opposing surface of the packaging substrate.

In one embodiment, a method of operation includes outputting the optical signals generated by the at least one electro-optical converter from the integrated circuit packaging structure through the opening in the second opposing surface of the packaging substrate, collimating the optical signals generated by the at least one electro-optical converter output from the bridge chip through the opening in the second opposing surface of the packaging substrate, focusing optical signals received through the opening in the second opposing surface of the packaging substrate to the at least one optical-electro converter and outputting electrical signals from the at least one host chip via at least one electrical through link extending from the first opposing surface of the bridge chip to the second opposing surface of the bridge chip.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a functional wiring diagram of one embodiment of an IC packaging structure disclosed in this specification.

FIG. 2 is a top view of a bridge chip of one embodiment of an IC packaging structure disclosed in this specification.

FIG. 3 is cross section of a bridge chip of one embodiment of an IC packaging structure disclosed in this specification.

FIG. 4 is a functional wiring diagram of one embodiment of an IC packaging structure having multiple bridge chips disclosed in this specification.

FIG. 5 is a cross sectional view of one embodiment of an IC packaging structure disclosed in this specification.

FIG. 6 is a bottom view of the IC packaging structure of FIG. 5.

FIG. 7 is a cross sectional view of one embodiment of an IC packaging structure disclosed in this specification.

FIG. 8 is a bottom view of the IC packaging structure of FIG. 7.

FIG. 9 is a flow diagram of one embodiment of the method disclosed in this specification.

FIG. 10 is a flow diagram of one embodiment of the method disclosed in this specification.

### DETAILED DESCRIPTION

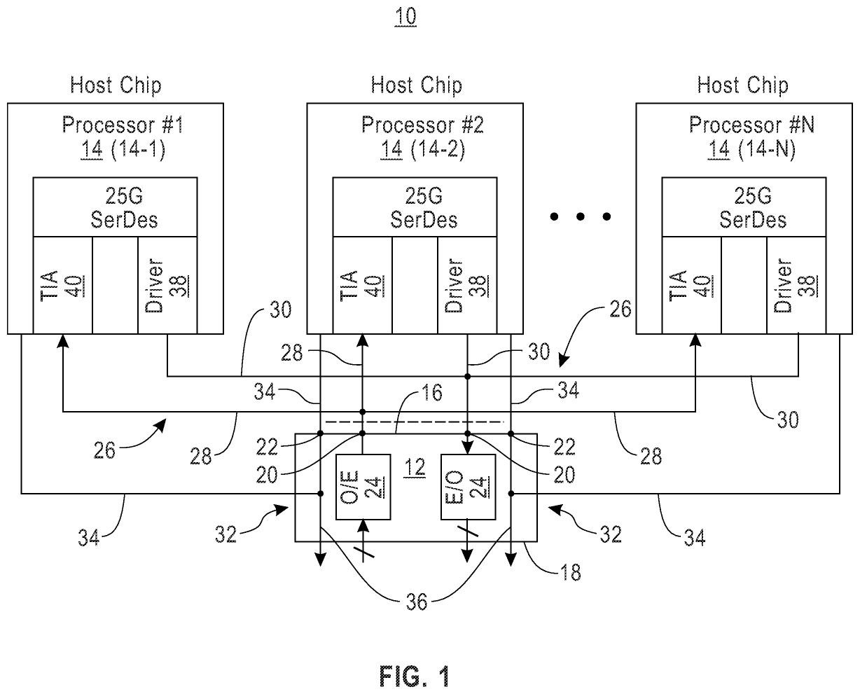

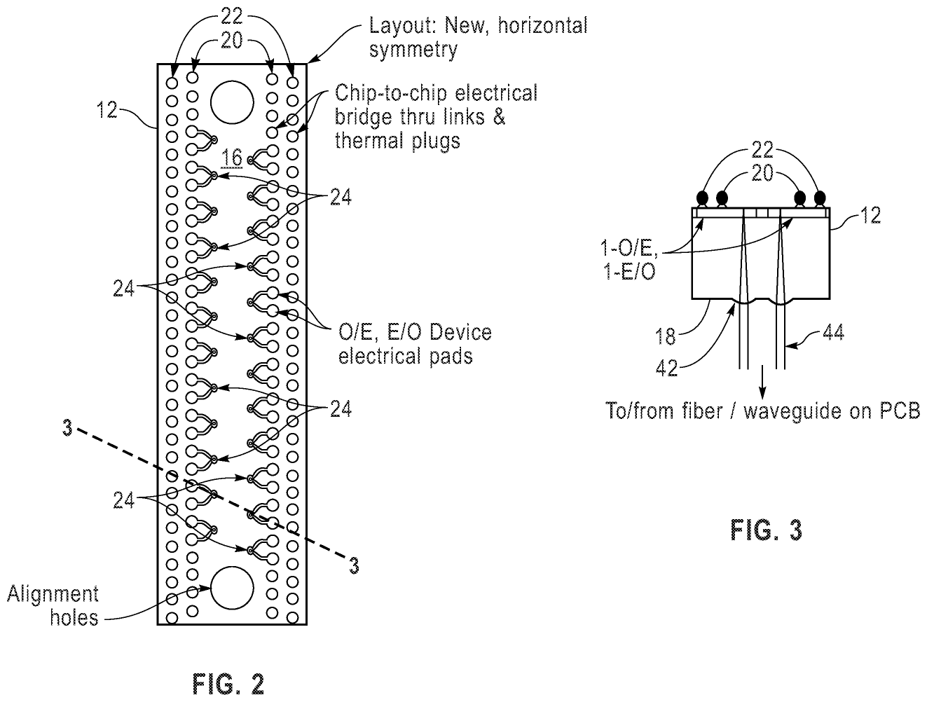

FIG. 1 is a functional wiring diagram of a first level IC packaging structure 10 having a bridge chip 12 and FIG. 2 is a top view of the bridge chip 12. The bridge chip 12 can be connected to one or more host chips 14. As shown in FIG. 1, the bridge chip 12 is connected to a plurality of host chips 14-1, 14-2 . . . 14-N. The number of host chips 14 may depend on the size of the bridge chip 12.

The bridge chip 12 has first and second opposing surfaces 16 and 18, respectively. As best seen in the top view of FIG. 2, the first opposing surface 16 has a plurality of first electrical connections 20 and a plurality of second electrical connections 22. In some embodiments, the first and second electrical connections 20 and 22 may be metal electrical interconnects deposited and defined on the bridge chip 12 wafers, with or without additional insulating or adhesion layers, wafer scale bonded and diced/singulated to dimensions.

The bridge chip 12 includes at least one converter 24. In the embodiment shown in FIG. 1, the bridge chip 12 includes an electro-optical converter 24-E/O and an optical-electro converter 24-O/E. The electro-optical converter 24-E/O is a semiconductor device embedded in the bridge chip 12 that converts an electrical signal to an optical signal, such as a VCSEL (vertical cavity self-emitting laser). The optical-electro converter 24-O/E is a semiconductor device embedded in the bridge chip 12 that converts an optical signal to an electrical signal, such as a photodiode.

As shown in FIG. 2, the bridge chip 12 may have a plurality of converters 24. The embodiment shown in FIG. 2 has two rows of converters 24. Each converter 24 is connected to a pair of electrical connections 20. Thus, the bridge 12 of FIG. 2 has a 2×12 array of converters. The converters 24 in the 2×12 array may all be electro-optical converters 24-E/O, all optical-electro converters 24-O/E or a combination of electro-optical converters 24-E/O and optical-electro converters 24-O/E. In one embodiment, one row of converters 24 may be electro-optical converters 24-E/O and the other row of converters 24 may be optical-electro converters 24-O/E. In some embodiments, the converters 24 can be single or arrays of VCSELs and/or photodiodes, including multidimensional arrays of single or multiple chips.

In one embodiment, the bridge chip 12 includes a first wiring pattern 26 that interconnects the least one converter 24 to a corresponding one or more host chips 14 using the plurality of first electrical connections 20. In one embodiment, as shown in FIG. 1, the first wiring pattern 26 includes one or more wirings layer 28 that connects each host chip 14 to a converter 24-O/E. The first wiring pattern 26 may also include one or more wiring layers 30 that connects each host chip 14 to a converter 24-E/O. In some embodiments, the first wiring pattern 26 interconnects the plurality of host chips 14 to each other. In one embodiment, the bridge chip 12 includes a second wiring pattern 32 electrically connected to one or more host chips 14 using the plurality of second electrical connections 22. In one embodiment, as shown in FIG. 1, the second wiring pattern 32 includes one or more wiring layers 34 electrically connecting the host chips 14 to one or more electrical through links 36. The electrical through links 36 enables electrically connecting the host chips 14 on the first level package to host chips on multiple first level packagers and/or on second or more level packages.

In one embodiment, the bridge chip 12 is provided in the IC package 10 much closer to the host chips 14 than in prior art IC package systems and to eliminate the intermediate interface layer all together required by the prior art systems. The IC package 10 thereby reduces power consumption and cost. In addition, in one embodiment, the IC package 10 enables the same bandwidth with less optics hardware by providing host chips interconnects and protocols. In one embodiment, the host chips 14 will directly drive the optical devices 24 using a drive circuit 38 and receive optical signals using a trans-impedance amplifier 40, using single-ended electrical interconnects 20 instead of differential, which will lead to an increased IO density. In one embodiment, the bridge chip 12 is mounted on the first level package in close proximity to host chips 14. Unlike conventional laser chips, the bridge chip 12 has the wiring pattern 26 to interconnect chips 14 on the same first level package.

In some embodiments, the wiring pattern 26 with communication protocol provided by the host chips 14 enables functionalities such as master/slave control and data queuing and multiplexing with fewer E/O and O/E devices among the connected host chips 14. Because of the ultra-short electrical interconnects between the host chips 14 and the bridge chip 12, the IC package 10 has increased data rate per lane, such as 50 Gb/s or more, saving on transceiver circuitry complexity in the host chips 14. In some embodiments, the short reach electrical connection from the host chips 14 to the bridge chip 12 enables different connection topologies between the host chips 14. For example, the first wiring pattern can connect the host chips 14 in topologies such as P2P, Bus, Ring, Star, Mesh, Tree or a hybrid that combines two or more of the above topologies.

In some embodiments, a reduction of optical power of greater than 2× is accomplished by the direct drive architecture and that eliminates conventional optical drive hardware. In addition, cost reduction of greater than 2× and reduction in substrate real estate of greater than 2× is accomplished by first wiring pattern 26 architecture that allows the optical drive hardware on the bridge chip 12 to be multiplexed by several host chips 14. In one embodiment, a master host chip controls the data clocking bandwidth and queue of the slave and master host chips 14 via a shared electrical thru link provided by the first wiring pattern 26.

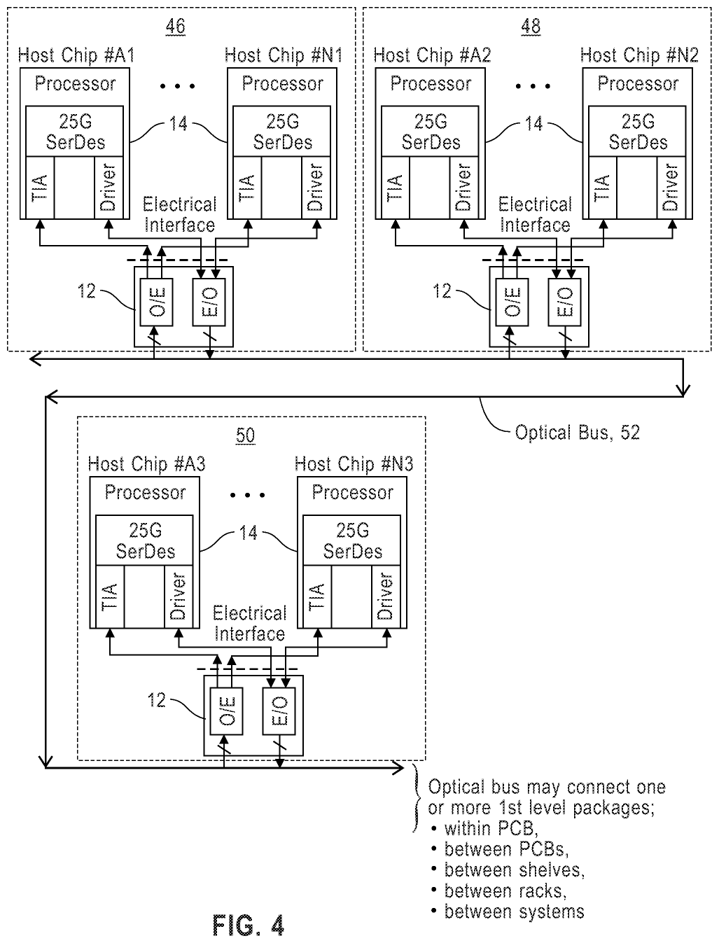

In one embodiment as shown in FIG. 3, an optical interface 42 is provided on the backside second opposed surface 18 of the bridge chip 12. FIG. 3 is cross section of the bridge chip 12 in FIG. 2 taken along lines 3-3. In one embodiment, the optical interface 42 is configured to output the optical signals generated by the one or more electro-optical converters 24-E/O from the second opposing surface 18. In addition, in one embodiment, the optical interface 42 is configured to receive optical signals through the second opposing surface 18 and to transmit the received optical signals to the at least one optical-electro converter 24-O/E. In one embodiment, the optical interface 42 is a lens configured to collimate the optical signals generated by the one or more electro-optical converters 24-E/O output from the bridge chip 12. In one embodiment, the lens 42 is configured to focus the received optical signals to the one or more optical-electro converters 24-E/O. In some embodiments, the optical interface 42 enables optically connecting the host chips 14 on the first level package to host chips on multiple first level packages and/or second or more level packages. For example, as shown in functional wiring diagram of FIG. 4, the bridge chips 12 in each of the first level package 46, first level package 48 and first level package 50 are connected to an optical bus 52. The optical bus 52 may connect one or more first level packages within a PCB, between PCBs, between shelves, between racks and/or between systems.

In some embodiments, the lens 42 is an optical transparent lens. In some embodiments, for optical transmission, the lens 42 may be of material transparent at the optical wavelength of the converters 24. For example, the lens 42 may be made of thermoset or epoxy clear plastic. In one embodiment, glass can be molded or etched to form the lens 42. In some embodiments, the lens 42 is optically transparent over a wide wavelength spectrum from UV to the infrared. In some embodiments, the optical emission form backside 18 is possible for wavelengths greater than or equal to 980 nm (980 nm, 1110 nm, 1330 nm and 1550 nm). In some embodiments, the backside lens 42 can be a separate component attached to backside 18 of the bridge chip 12. In some embodiments, the backside lens 42 can be formed from the substrate material of the bridge chip by photoresist reflowing and etching with dry (RIE) or wet (HF) etches. The lens 42 may be concave or convex and can provide an optical path 44 that is focusing and/or collimating. In some embodiments, the lens 42 may be a lens array matching the array of converters 24 as shown in FIG. 2.

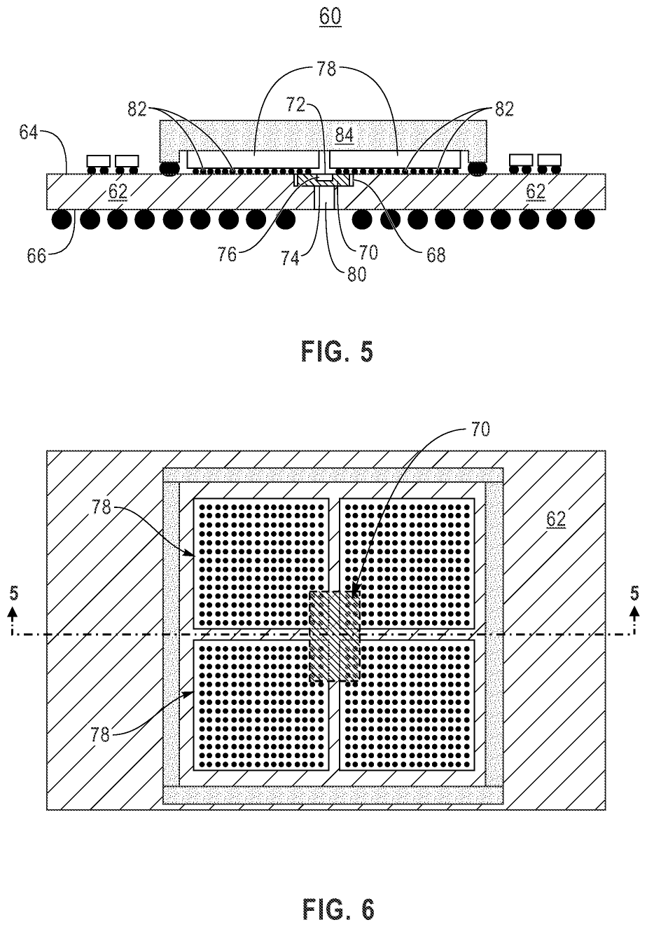

FIG. 5 is a cross sectional view of one embodiment of an IC package 60. The package 60 includes a packaging substrate 62 having first and second opposing surfaces 64 and 66, respectively. The substrate 62 may be an interposer or a carrier. A trench 68 is provided in the first opposing surface 64 of the packaging substrate 62. A bridge chip 70 is disposed in the trench 68. The bridge chip 70 has the same structure and features of bridge chip 12 described above, including first and second opposing surfaces 72 and 74, the first opposing surface having a plurality of first electrical connections (not shown) and a plurality of second electrical connections (not shown), at least one converter 76. The at least one converter 76 being at least one of an electro-optical converter and an optical-electro converter. A first wiring pattern (not shown) interconnects the least one converter 76 to a corresponding at least one host chip 78 using the plurality of first electrical connections and a second wiring pattern (not shown) is electrically connected to the at least one host chip 78 using the plurality of second electrical connections. An opening 80 is provided in the second opposing surface 66 of the packaging substrate 62. The opening 80 extends to the second opposing surface 74 of the bridge chip 70. At least one host chip 78 is overlying the first opposing surface 72 of the bridge chip 70 and the first opposing surface 64 of the packaging substrate 62. The at least one host chip 78 is directly connected to the first opposing surface 72 of the bridge chip 70 and the first opposing surface 64 of the packaging substrate 62 by a plurality of electrical connections 82. The optical signals generated by the E/O converter of the bridge chip 70 are output from the integrated circuit packaging structure 60 through the opening 80 in the second opposing surface 66 of the packaging substrate 62. In some embodiments, the packaging structure 60 may include a lid 84.

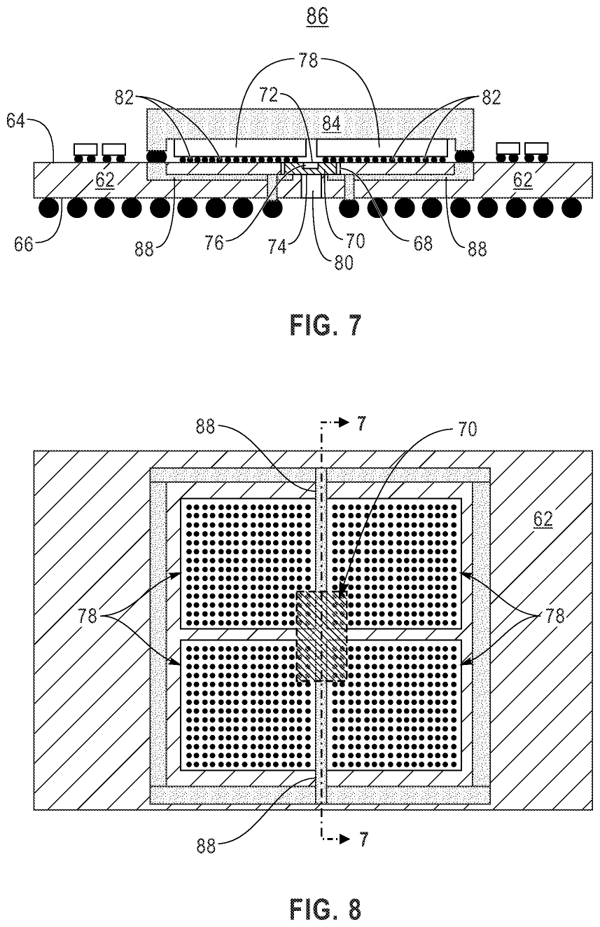

FIG. 6 is a bottom view of the packaging structure 60 with the substrate 62 being transparent for clarity. FIG. 5 is a cross section of FIG. 6 taken along lines 5-5. In this embodiment, four host chips 78 overlay the bridge chip 70. The position of the bridge chip 70 under the host chips 78 is shown in dashed lines. In some embodiments, the packaging structure 60 may include an additional thermal conductivity path to the package lid 84. FIG. 7 is a cross section of the packaging structure 86 having a thermal conductivity path 88. FIG. 8 is a bottom view of the packaging structure 86 with the portion of the substrate removed below the thermal conductivity path 88. FIG. 7 is cross section taken along lines 7-7 of FIG. 8.

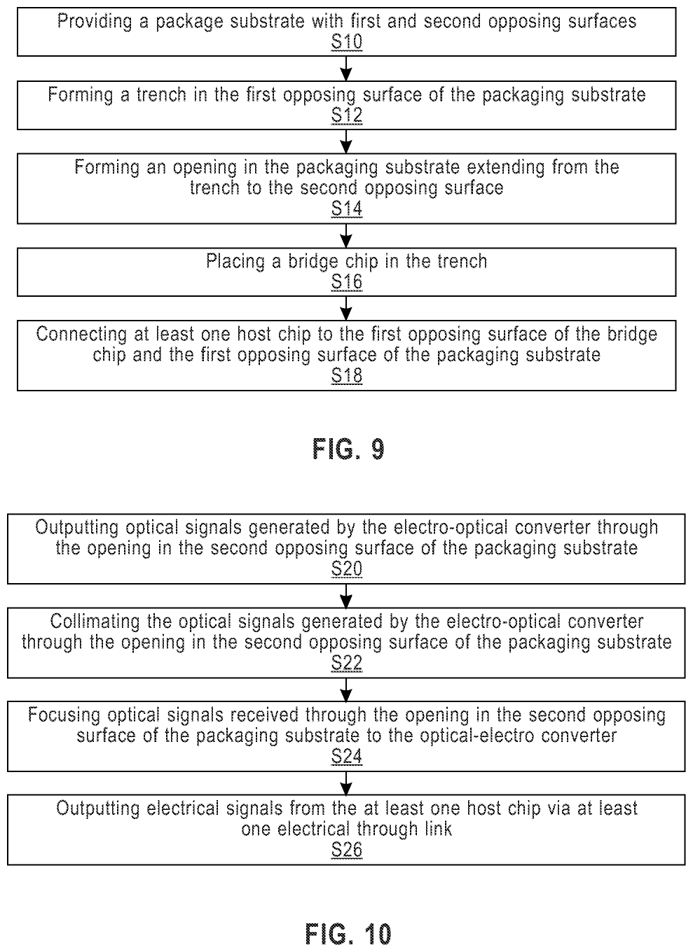

FIG. 9 is a flow chart for one embodiment of a method for forming an integrated circuit packaging structure. The method includes step S10 of providing a packaging substrate comprising first and second opposing surfaces, step S12 of forming a trench in the first opposing surface of the packaging substrate, step S14 of forming an opening in the packaging substrate extending from the trench to the second opposing surface and step S16 of placing a bridge chip in the trench. In some embodiments, the bridge chip includes first and second opposing surfaces, the first opposing surface having a plurality of first electrical connections and a plurality of second electrical connections, at least one converter that includes at least one of an electro-optical converter and an optical-electro converter, a first wiring pattern interconnecting the least one converter to a corresponding at least one host chip using the plurality of first electrical connections; and a second wiring pattern electrically connected to the at least one host chip using the plurality of second electrical connections. The method further includes step S18 of connecting the at least one host chip to the first opposing surface of the bridge chip and the first opposing surface of the packaging substrate, the at least one host chip being directly connected to the first opposing surface of the bridge chip and the first opposing surface of the packaging substrate. There may be other packaging steps known to those in the art, such as providing an underfill between the host chips and the first opposing surface of the bridge chip, and/or having an underfill material between the second surface of the packaging substrate and the printed circuit board beneath the packaging substrate so as to prevent dust, contaminants, etc., from interfering with the optical path to the O/E or from the E/O.

As shown in FIG. 10, a method of operation in one embodiment includes step S20 of outputting the optical signals generated by the at least one electro-optical converter from the integrated circuit packaging structure through the opening in the second opposing surface of the packaging substrate. The method of operation may also include step S22 of collimating the optical signals generated by the at least one electro-optical converter output from the bridge chip through the opening in the second opposing surface of the packaging substrate, step S24 of focusing optical signals received through the opening in the second opposing surface of the packaging substrate to the at least one optical-electro converter and step S26 of outputting electrical signals from the at least one host chip via at least one electrical through link extending from the first opposing surface of the bridge chip to the second opposing surface of the bridge chip.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below”, or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

It is to be understood that the various layers and/or regions shown in the accompanying drawings are not drawn to scale, and that one or more layers and/or regions of a type commonly used in complementary metal-oxide semiconductor (CMOS), fin field-effect transistor (FinFET), metal-oxide-semiconductor field-effect transistor (MOSFET), and/or other semiconductor devices, may or may not be explicitly shown in a given drawing. This does not imply that the layers and/or regions not explicitly shown are omitted from the actual devices. In addition, certain elements could be left out of particular views for the sake of clarity and/or simplicity when explanations are not necessarily focused on the omitted elements. Moreover, the same or similar reference numbers used throughout the drawings are used to denote the same or similar features, elements, or structures, and thus, a detailed explanation of the same or similar features, elements, or structures will not be repeated for each of the drawings.

The semiconductor devices and methods for forming same in accordance with embodiments of the present invention can be employed in applications, hardware, and/or electronic systems. Suitable hardware and systems for implementing embodiments of the invention can include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

The embodiments of the present invention can be used in connection with semiconductor devices that could require, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

It will also be understood that when an element, such as a layer, region, or substrate is referred to as being “on” or “over” another element, it can be directly on the other element or intervening elements can also be present. In contrast, when an element is referred to as being “directly on” or “directly over” another element, there are no intervening elements present, and the element is in contact with another element.

In addition, while preferred embodiments of the present invention have been described using specific terms, such description is for illustrative purposes only, and it is to be understood that changes and variations may be made without departing from the spirit or scope of the following claims.

What is claimed is:

1. A bridge chip comprising:
first and second opposing surfaces, the first opposing surface having a plurality of first electrical connections and a plurality of second electrical connections;
at least one converter, the at least one converter comprising at least one of an electro-optical converter and an optical-electro converter, the electro-optical converter configured to convert an electrical signal to an optical signal and the optical-electro converter configured to convert an optical signal to an electrical signal;
a first wiring pattern interconnecting the least one converter to a corresponding at least one host chip using the plurality of first electrical connections; and
a second wiring pattern electrically connected to the at least one host chip using the plurality of second electrical connections.

2. The bridge chip of claim 1, wherein the first wiring pattern interconnects a plurality of host chips to each other.

3. The bridge chip of claim 1, wherein the first wiring pattern interconnects the plurality of host chips in a topology selected from the group consisting of Point-to-Point (P2P), Bus, Ring, Star, Mesh, Tree and a hybrid that combines two or more topologies.

4. The bridge chip of claim 1, wherein the bridge chip further includes an optical interface configured to output the optical signals generated by the at least one electro-optical converter from the second opposing surface and configured to receive optical signals through the second opposing surface and to transmit the received optical signals to the at least one optical-electro converter.

5. The bridge chip of claim 4, wherein the optical interface comprises a lens on the second opposing surface configured to collimate the optical signals generated by the at least one electro-optical converter output from the bridge chip.

6. The bridge chip of claim 5, wherein the lens is configured to focus the received optical signals to the at least one optical-electro converter.

7. The bridge chip of claim 1, further comprising at least one electrical through link connected to the second wiring pattern, the at least one electrical through link extending from the first opposing surface to the second opposing surface, the at least one electrical through link being configured to output electrical signals from the at least one host chip.

8. An integrated circuit packaging structure comprising:
a packaging substrate comprising first and second opposing surfaces,
a trench provided in the first opposing surface of the packaging substrate;
a bridge chip disposed in the trench, the bridge chip comprising:
first and second opposing surfaces, the first opposing surface having a plurality of first electrical connections and a plurality of second electrical connections;
at least one converter, the at least one converter comprising at least one of an electro-optical converter and an optical-electro converter, the electro-optical converter configured to convert an electrical signal to an optical signal and the optical-electro converter configured to convert an optical signal to an electrical signal;
a first wiring pattern interconnecting the least one converter to a corresponding at least one host chip using the plurality of first electrical connections; and
a second wiring pattern electrically connected to the at least one host chip using the plurality of second electrical connections;
an opening provided in the second opposing surface of the packaging substrate, the opening extending to the second opposing surface of the bridge chip; and
at least one host chip overlying the first opposing surface of the bridge chip and the first opposing surface of the packaging substrate, the at least one host chip being directly connected to the first opposing surface of the bridge chip and the first opposing surface of the packaging substrate by a plurality of electrical connections;
wherein the optical signals are output from the integrated circuit packaging structure through the opening in the second opposing surface of the packaging substrate.

9. The integrated circuit packaging structure of claim 1, wherein the first wiring pattern interconnects a plurality of host chips to each other.

10. The integrated circuit packaging structure of claim 8, wherein the first wiring pattern interconnects the plurality of host chips in a topology selected from the group consisting of P2P, Bus, Ring, Star, Mesh, Tree and a hybrid that combines two or more topologies.

11. The integrated circuit packaging structure of claim 8, wherein the bridge chip further includes an optical interface configured to output the optical signals generated by the at least one electro-optical converter from the second opposing surface, and to receive optical signals through the second opposing surface and to transmit the received optical signals to the at least one optical-electro converter.

12. The integrated circuit packaging structure of claim 11, wherein the optical interface comprises a lens on the second opposing surface configured to collimate the optical signals generated by the at least one electro-optical converter output from the bridge chip.

13. The integrated circuit packaging structure of claim 12, wherein the lens is configured to focus the received optical signals to the at least one optical-electro converter.

14. The integrated circuit packaging structure of claim 8, further comprising at least one electrical through link connected to the second wiring pattern, the at least one electrical through link extending from the first opposing surface to the second opposing surface, the at least one electrical through link being configured to output electrical signals from the plurality of host chips.

15. The integrated circuit packaging structure of claim 11, further comprising a lens embedded in the first opposing surface of the packaging substrate configured to collimate the optical signals generated by the at least one electro-optical converter output from the bridge chip and to focus the received optical signals to the at least one optical-electro converter.

16. The integrated circuit packaging structure of claim 8, further comprising a lid connected to the first opposing surface of the packaging substrate and at least one thermal conductive layer in the packaging substrate, the at least one thermal conductive layer being connected to at least one of the lid and to electrical connections on the second opposing surface of the packaging substrate.

17. A method for forming an integrated circuit packaging structure comprising:
providing a packaging substrate comprising first and second opposing surfaces,
forming a trench in the first opposing surface of the packaging substrate;
forming an opening in the packaging substrate extending from the trench to the second opposing surface;
placing a bridge chip in the trench, the bridge chip comprising:
first and second opposing surfaces, the first opposing surface having a plurality of first electrical connections and a plurality of second electrical connections;
at least one converter, the at least one converter comprising at least one of an electro-optical converter and an optical-electro converter, the electro-optical converter configured to convert an electrical signal to an optical signal and the optical-electro converter configured to convert an optical signal to an electrical signal;
a first wiring pattern interconnecting the least one converter to a corresponding at least one host chip using the plurality of first electrical connections; and
a second wiring pattern electrically connected to the at least one host chip using the plurality of second electrical connections; and
connecting the at least one host chip to the first opposing surface of the bridge chip and the first opposing surface of the packaging substrate, the at least one host chip being directly connected to the first opposing surface of the bridge chip and the first opposing surface of the packaging substrate;
wherein the optical signals generated by the at least one electro-optical converter are output from the integrated circuit packaging structure through the opening in the second opposing surface of the packaging substrate.

18. The method for forming an integrated circuit packaging structure of claim 17, further comprising collimating the optical signals generated by the at least one electro-optical converter output from the bridge chip through the opening in the second opposing surface of the packaging substrate.

19. The method for forming an integrated circuit packaging structure of claim 17, further comprising focusing optical signals received through the opening in the second opposing surface of the packaging substrate to the at least one optical-electro converter.

20. The method for forming an integrated circuit packaging structure of claim 17, further comprising outputting electrical signals from the at least one host chip via at least one electrical through link extending from the first opposing surface of the bridge chip to the second opposing surface of the bridge chip.
